(19) United States
(12) Patent Application Publication
(10) Pub. No.: US 2005/0153543 A1
(43) Pub. Date: Jul. 14, 2005

(54) Method of forming self aligned contact

(75) Inventors: Shui-Chin Huang, Tainan City (TW); Chien-Hung Chen, Hsin-Chu City (TW)

Correspondence Address: SQUIRE, SANDERS & DEMPSEY L.L.P, 600 HANSEN WAY, PALO ALTO, CA, 94304-1043, US

(73) Assignee: United Microelectronics Corp, Hsin-Chu City (TW)

(21) Appl. No.: 10/753,657

(22) Filed: Jan. 8, 2004

(51) Int. Cl. H01L 21/4763; H01L 21/336; H01L 21/44

(52) U.S. Cl. 438/639; 438/597; 438/257; 438/279

(57) ABSTRACT

A self-aligned contact method includes, firstly, forming a plurality of stack structures on a semiconductor substrate. The stack structures separate each other and each has a first polysilicon layer, an insulating layer on the first polysilicon layer and a second polysilicon layer on the insulating layer. Secondly, a spacer forms on the sidewall of the stack structures, and then a dielectric layer is formed on the stack structures, the spacers and the semiconductor substrate. Finally, the portion of the second polysilicon layer is used as a buffer for forming a contact window by removing a portion of the dielectric layer. The contact window is located between two stack structures.

### BACKGROUND OF THE INVENTION

1. Field of the Invention

The present invention relates to a method in the manufacture of a self-aligned contact and more particularly to the method of forming a self-aligned contact in a memory device cell.

2. Description of the Prior Art

Flash memory is a kind of non-volatile memory device which stores data by injecting the electrons into a floating gate and removing the electrons from the floating gate. Because the demand of high storage capacity and miniaturization of the memory device, how to manufacture a flash memory structure with high density and high storage capacity becomes an important subject now. Recently, the stack gate structure is widely used in memory device manufacture, because the space is packed in the small cells, the problem of the prior art can be solved by various stack gate structure designs. U.S. Pat. No. 5,658,813 mentioned a method of preventing the active region of the silicon substrate to be damaged when etching the dielectric layer by forming a stack gate structure. Besides, self-aligned contact (SAC) also widely used in various integrated circuit manufactures, to reduce the contact window etching failures and form a contact with a smaller size. Referring to FIG. 1A, the prior art of a self-aligned contact, is used to form a traditional MOS transistor gate. First, forming a stack structure comprises a silicon substrate 100, an isolating layer 110 on the silicon substrate 100, a polysilicon 120 on the isolating layer 110, and a silicide 130 (such as WSi₂) on the polysilicon 120. Forming a hard mask 140 (such as Si₃N₄) on the silicide 130, and patterned to remove a part of the stack structure, to form a plurality of stack gate structure separately. As shown in FIG. 1B, forming a spacer 150 on the sidewall of each stack gate structure is used to stop contact window etching and to prevent shorting. Sequentially, forming a dielectric layer 160 on the stack gate structures. Finally, as shown in FIG. 1C, using self-aligned contact to etch the contact window and setting the etching range that is larger than the range between the two stack gate structures. Because the etching selectivity of Si₃N₄ is high, it's more difficult to etch the hard mask 140 and the spacer 150 than the dielectric layer 160. It is capable to etch the contact clearly until the surface of the silicon substrate 100, and without the stack gate structure becoming damaged.

For integrate circuit process with high integration and miniaturization, the above-mentioned self-aligned contact not only can reduce the space between circuits, but also prevent exposure failure, mis-alignment, short and open when contact window etching.

The structure of flash memory cell mainly comprises semiconductor substrate, isolating layer, floating gate and control gate. Electrons are injected into and removed from the floating gate for data storage, Control gate is used to control the bit line. Referring to FIG. 2, an example of the structure of p-channel flash memory. First, providing a silicon substrate 200, and forming a stack structure comprises a gate dielectric 210, a first polysilicon layer 220, an isolating layer 230 and a second polysilicon layer 240. Then the stack structure is patterned and a plurality of stack structures 250 are formed separately. Forming a spacer 260 on the sidewall of the stack structures 250 and forming a dielectric layer 270 on the stack structures 250, the spacer 260 and the holes between two stack structure 250. Finally, etching contact window 280. It is the fundamental process of flash memory cell structure.

### SUMMARY OF THE INVENTION

One objective of the present invention is to use the useless polysilicon to be a buffer when etching the contact window, it means that the useless dummy gate replaces the function of the traditional hard mask.

The other objective of the present invention is to use the self aligned contact to etching contact window and use the useless polysilicon to be a buffer, to reduce the contact window size and process improvement.

A self-aligned contact method includes, firstly, forming a plurality of stack structures on a semiconductor substrate. The stack structures separate each other and each has a first polysilicon layer, an insulating layer on the first polysilicon layer and a second polysilicon layer on the insulating layer. Secondly, a spacer forms on the sidewall of the stack structures, and then a dielectric layer forms on the stack structures, the spacers and the semiconductor substrate. Finally, the portion of the second polysilicon layer is used as a buffer for forming a contact window by removing a portion of the dielectric layer. The contact window is located between two stack structures.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A-FIG. 1C shows an illustrative chart of the steps for applying self aligned contact to manufacture MOS transistor;

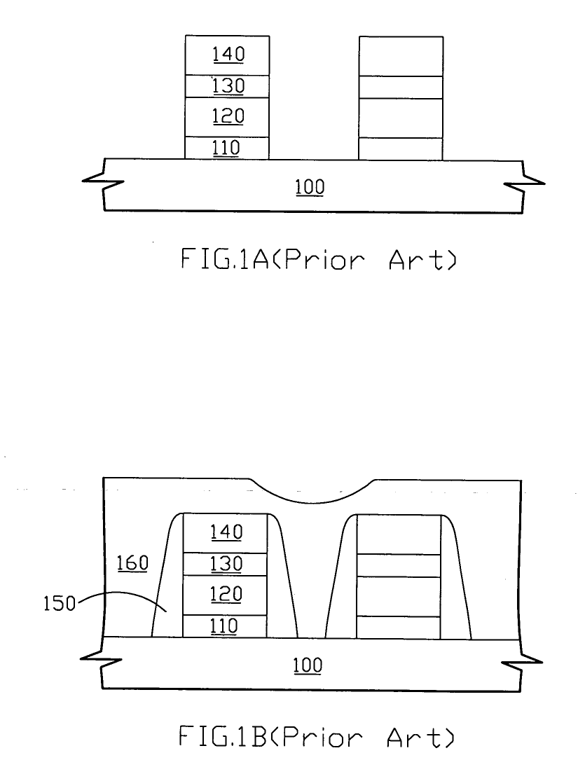

FIG. 2 shows an illustrative chart of flash memory cell of the prior art;

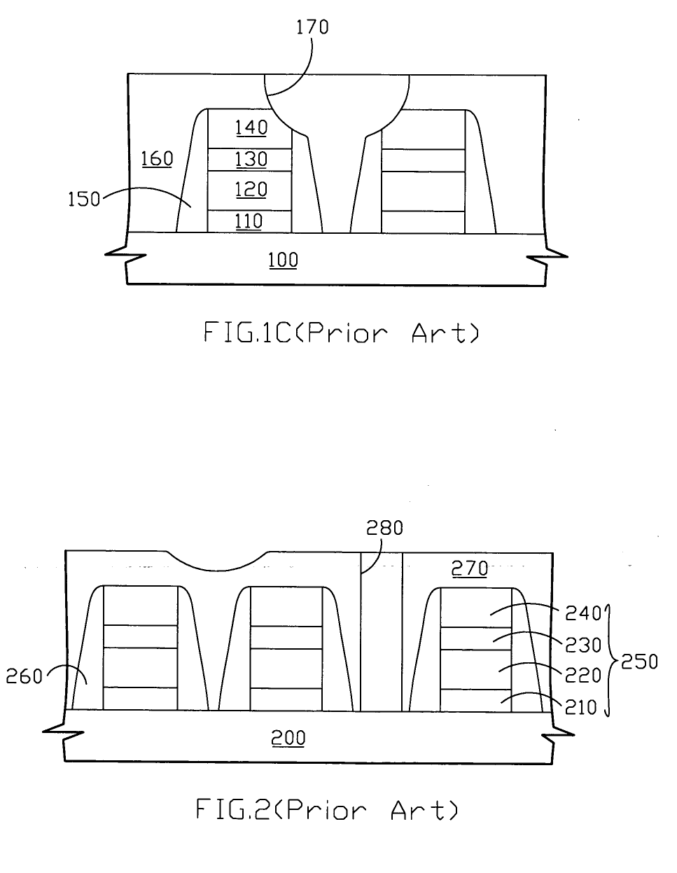

FIG. 3A-FIG. 3C shows cross-sectional diagrams illustrating the steps of the poly buffered self aligned contact in the invention; and

FIG. 4 shows cross-sectional diagrams illustrating another embodiment in the invention.

### DESCRIPTION OF THE PREFERRED EMBODIMENT

Some embodiments of the invention will be described exquisitely as below. Besides, the invention can also be practiced extensively in other embodiments. That is to say, the scope of the invention should not be restricted by the proposed embodiments. The scope of the invention should be based on the claims proposed later. Then, the components of the semiconductor devices are not shown to scale. Some dimensions are exaggerated to the related components to provide a more clear description and comprehension of the present invention.

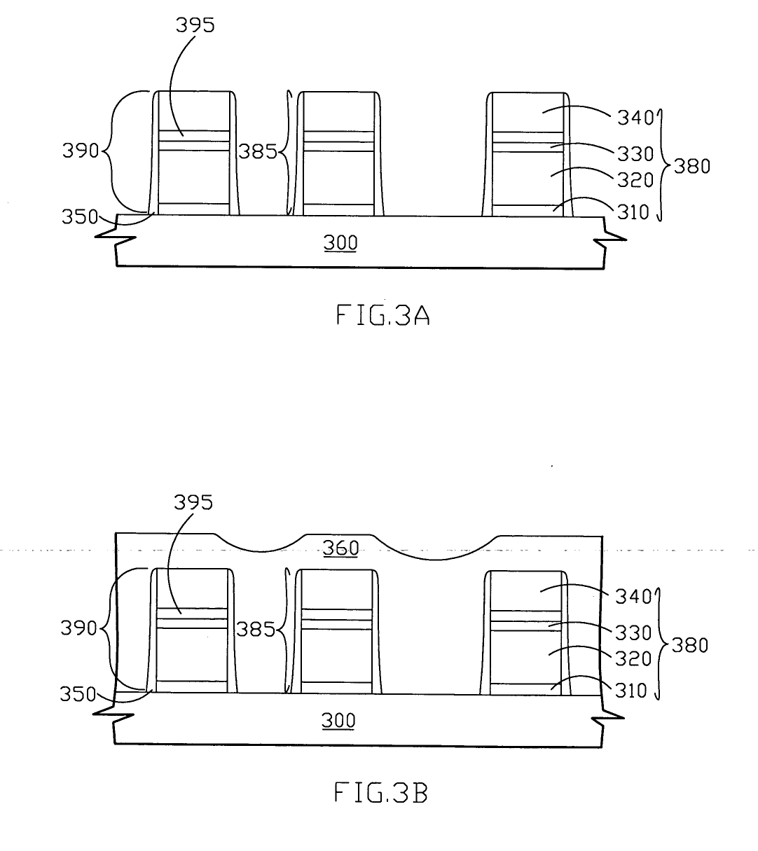

In the first preferred embodiment of the present invention, as shown in FIG. 3A-3D. Referring to FIG. 3A, a gate dielectric 310 is formed on a semiconductor substrate 300, wherein the semiconductor substrate 300 is a doped silicon wafer and the gate dielectric 310 is a silicon dioxide layer. Then, a first polysilicon layer 320 is formed on the gate dielectric 310, and the first polysilicon layer 320 can be formed by a chemical vapor deposition (CVD) process to be a floating gate in cells. Alternatively, the first polysilicon layer 320 is required for no specific purpose. An isolating layer 330 is formed on the first polysilicon layer 320 to prevent shorting between the gates, in this embodiment, the isolating layer 330 is an oxide-nitride-oxide (ONO) structure, such as an SiO₂/Si₃N₄/SiO₂ structure. The Si₃N₄ of the ONO structure is used to enhance the ability of isolate dopes and improve the dielectric constant, and SiO₂ is used to improve the intensity of the interface between polysilicon and nitride. Finally, a second polysilicon layer 340 is formed on the isolating layer 330, the second polysilicon layer 340 can be formed by a chemical vapor deposition (CVD) process to be a control gate in cells. Alternatively, the second poly layer 340 is a dummy gate for no specific purpose. The stack structure in cells is composed of the gate dielectric 310, the first polysilicon layer 320, the isolating layer 330 and the second polysilicon layer 340. Besides, a dielectric 395 can be formed between the isolating layer 330 and the second polysilicon layer 340, to be a resist when the isolating layer 330 is etched.

Then the stack structure is patterned, removing a part of the stack structure and forming a plurality of stack structures 380, 385 and 390 separately. Wherein the gate dielectric 310, the first polysilicon layer 320, the isolating layer 330 and the second polysilicon layer 340 is etched and exposes a part of the surface of the semiconductor substrate 300, as shown in FIG. 3A. The above-mentioned process of forming a plurality of stack structures 380, 385 and 390 by etching will not be described particularly in this embodiment because it's a prior art in related technology, and the patterned structure is directly shown.

The first polysilicon layer 320 of the stack structure 380 and the stack structure 385 are used to be a gate electrode and are useless for a typical transistor control device. Therefore, the second polysilicon layer 340 of the stack structure 380 and the stack structure 385 become dummy gates. On the other hand, the stack structure 390 is used for a memory cell, and the first polysilicon layer 320 of the stack structure 390 is a floating gate and the second polysilicon layer 340 of the stack structure 390 is a control gate. After the pattern transfer process, doping on the surface of the semiconductor substrate 300 by ion implantation or light doped drain (LDD) is to form the source and drain regions on the surface of the semiconductor substrate 300. The source region, the drain region and the polarity of different regions are not shown in the figures of the present invention.

After the ion implantation process, referring to FIG. 3B, in order to prevent shorting on the sidewalls of the stack structures, it is necessary to form a spacer 350 on the sidewall of each stack poly structure, to be an isolator and a stop layer when etching the contact window. The way to form the spacer 350 is to deposit a multi-layer isolator structure on the surface sidewall of the stack structures and the exposed surface of the semiconductor substrate 300 regularly, and remove a part of the multi-layer isolator structure by wet etching. In the present embodiment, the spacer 350 is a silicon nitride (Si₃N₄) or an oxide-nitride-oxide structure, such as a SiO₂/Si₃N₄/SiO₂ film. Sequentially, forming a dielectric layer 360 on the stack structure 380, 385 and 390 and filling in the holes between the stack structures. The dielectric layer 360 is silicon dioxide in the embodiment.

Finally is the process of contact window etching. Mentioned above, the first polysilicon layer 320 is used to be a floating gate and the second polysilicon layer is used to be a control gate in each stack structure. But, the floating gates next to the contact window 370 are not used to inject or remove electrons. Therefore, the second polysilicon layer 340 of the floating gates next to the contact window 370 become useless dummy gates. The character of the present invention is to use useless dummy gates to be buffer when contact window etching, to reduce contact window size and process improvement.

As shown in FIG. 3C, pattern transfer for the dielectric 360 and set a range with a larger size than the hole between two stack structures when etching the dielectric layer 360. During etching, the surplus etch range is stopped by the dummy gates and the spacer 350, and a part of the dummy gates and the spacer 350 will be damaged. Because the etching selectivity of poly and silicon nitride compare with Silicon Dioxide is high, the dielectric layer 360 consist of Silicon Dioxide will be easily etched. Consequently, the process of contact etching can be done effectually even in mis-alignment, and without over etching. Finally, forming a contact plug 375 in contact window 370 and contact plug 375 contacts the semiconductor substrate 300 electrically.

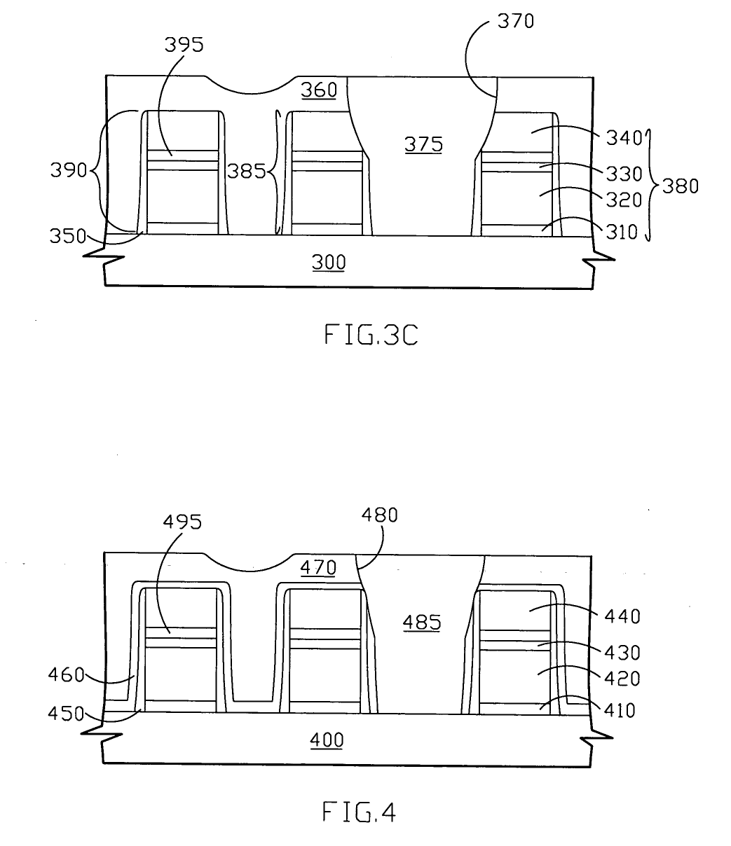

Another embodiment of the present invention, as shown in FIG. 4, providing a semiconductor substrate 400 and forming a stack structure comprises a gate dielectric 410, a first polysilicon layer 420, an isolating layer 430 and a second polysilicon layer 440 first. Then, the stack structure is patterned appropriately to form a plurality of stack structures. Besides, a dielectric 495 can be formed to be a mask between the isolating layer 430 and the second polysilicon layer 440. Second, forming a spacer 450 on the sidewall of the plurality of stack structures, forming a barrier layer 460 on the plurality of stack structures, the spacers 450 and the semiconductor substrate 400. And forming a dielectric layer 470 on the barrier layer 460. Finally, a self-aligned contact is used in etching the contact window 480, and forming a contact plug 485 in contact window 480 and contact plug 485 contacts semiconductor substrate 400 electrically. Wherein the barrier layer 460 is an oxide, a nitride or a multi-layer structure consists of oxide and nitride.

Although specific embodiments have been illustrated and described, it will be obvious to those skilled in the art that various modifications may be made without departing from what is intended, but not to be limited solely by the appended claims.

1. A method of forming self aligned contact, comprising:
providing a semiconductor substrate;
forming a plurality of stack structures on said semiconductor substrate, said plurality of stack structures separating each other and each comprising a first polysilicon layer, an isolating layer on said first polysilicon layer and a second polysilicon layer on said isolating layer;
forming a spacer on a sidewall of each said stack structure;
forming a first dielectric layer on said plurality of stack structures, said plurality of spacers and said semiconductor substrate; and
removing a portion of said first dielectric layer, with a portion of said plurality of second polysilicon layer as a buffer, to form a contact window between partial two said stack structures.

2. The method according to claim 1, wherein said isolating layer comprises an oxide layer.

3. The method according to claim 1, wherein said isolating layer comprises a nitride layer.

4. The method according to claim 1, wherein said isolating layer is an oxide-nitride-oxide (ONO) structure.

5. The method according to claim 1, further comprising forming a second dielectric layer between said isolating layer and said second polysilicon layer.

6. The method according to claim 1, wherein said first dielectric layer is a silicon dioxide (SiO2) layer.

7. The method according to claim 1, wherein said spacer comprises a nitride layer.

8. The method according to claim 1, wherein said spacer comprises a multi-layer structure consists of an oxide layer and a nitride layer.

9. The method according to claim 1, further comprising forming a gate dielectric between said semiconductor substrate and said first polysilicon layer in each said stack structure.

10. The method according to claim 1, further comprising forming a contact plug in said contact window, wherein said contact plug contacts said semiconductor substrate electrically.

11. A method of forming polysilicon-buffered self aligned contact, said method comprising:
providing a semiconductor substrate;
forming a plurality of stack structures on said semiconductor substrate, said plurality of stack structures separating each other and each comprising a first polysilicon layer, an isolating layer on said first polysilicon layer and a second polysilicon layer on said isolating layer, wherein a portion of said plurality of second polysilicon layers are a plurality of dummy gates;
forming a spacer on said sidewall of each said stack structure;
forming a barrier layer on said plurality of stack structures, said plurality of spacers and said semiconductor substrate;
blanketing a first dielectric layer on said barrier layer;
removing a portion of said first dielectric layer, with said plurality of dummy gates as a buffer, to form a contact window between any two of said stack structures each that comprises said dummy gate; and
forming a contact plug in said contact window, wherein said contact plug electrically connects said semiconductor substrate.

12. The method of claim 11, wherein said isolating layer comprises an oxide layer.

13. The method of claim 11, wherein said isolating layer is an oxide-nitride-oxide (ONO) structure.

14. The method of claim 11, further comprising forming a second dielectric layer between said isolating layer and said second polysilicon layer.

15. The method of claim 11, wherein said spacer comprises a nitride layer.

16. The method of claim 11, wherein said spacer comprises a multi-layer structure consisting of an oxide layer and a nitride layer.

17. The method of claim 11, wherein said barrier layer comprises an oxide layer.

18. The method of claim 11, wherein said barrier layer comprises a nitride layer.

19. The method of claim 1, wherein said barrier layer comprises a multi-layer structure consisting of an oxide layer and a nitride layer.
